(19) United States
(12) Patent Application Publication
(10) Pub. No.: US 2023/0383185 A1
(43) Pub. Date: Nov. 30, 2023

(54) ETCHANT COMPOSITION AND METHOD

(71) Applicant: ENTEGRIS, INC., Billerica, MA (US)

(72) Inventors: JeongYeol Yang, Gwangju-si (KR); Hyungpyo Hong, Bundang-gu (KR); Juhee Yeo, Suwon (KR); SeongJin Hong, Cheongju-si (KR); WonLae Kim, Gunpo-si (KR)

(21) Appl. No.: 18/202,007

(22) Filed: May 25, 2023

Related U.S. Application Data
(60) Provisional application No. 63/346,748, filed on May 27, 2022.

(51) Int. Cl. C09K 13/08; C09K 15/20

(52) U.S. Cl. CPC C09K 13/08; C09K 15/20

(57) ABSTRACT

Compositions and methods for selectively etching titanium nitride, cobalt, or a combination thereof. The compositions and methods generally leave molybdenum and other materials present unaffected by the process. The process can achieve a high etching rate, and can provide uniform recess top and bottom layers in patterns.

### FIELD

The present disclosure relates to the field of semiconductor manufacturing. In particular, the disclosure relates to etchant compositions and methods for etching of titanium nitride films.

### PRIORITY

The present disclosure claims priority to U.S. provisional patent No. 63/346,748, with a filing date of May 27, 2022. The priority document is hereby incorporated by reference.

### BACKGROUND

Photoresist masks can be used to pattern materials such as semiconductors or dielectrics. For example, photoresist masks can be used in a dual damascene process to form interconnects in the back-end metallization of a microelectronic device. The dual damascene process can involve forming a photoresist mask on a low-k dielectric layer overlying a metal conductor layer, such as a copper layer. The low-k dielectric layer can be etched according to the photoresist mask to form a trench that exposes the metal conductor layer. The trench, commonly known as dual damascene structure, is usually defined using two lithography steps. The photoresist mask is then removed from the low-k dielectric layer before a conductive material is deposited into the trench to form an interconnect.

### SUMMARY

In some embodiments, metal masks are used to provide better profile control of trenches. The metal hard masks can be made of titanium or titanium nitride, and are removed by a wet etching process after forming the trench of the dual damascene structure. In some embodiments, the wet etching process uses a removal chemistry that effectively removes the metal hard mask and/or photoresist etch residues without affecting the underlying metal conductor layer and low-k dielectric material, or other materials on the microelectronic device. Some embodiments of the etchant compositions can be utilized in a wet-etching process to selectively remove substances such as titanium nitride, while being compatible with metal conducting layers (e.g., molybdenum, AlOₓ, SiOₓ, or polysilicon)

In some embodiments, a composition comprises an oxidizing agent; an etchant; a first corrosion inhibitor; and a second corrosion inhibitor, wherein the second corrosion inhibitor includes a N-hetero-atom-containing aromatic compound.

In some embodiments of the composition, the first corrosion inhibitor inhibits chemical reaction of a first material, wherein the first material includes Cr, Mo, W, or any combination thereof.

In some embodiments of the composition, the second corrosion inhibitor inhibits chemical reaction of a second material.

In some embodiments of the composition, the first corrosion inhibitor comprises 5-methylbenzotriazole.

In some embodiments of the composition, the second corrosion inhibitor comprises polyvinylpyrrolidone.

In some embodiments of the composition, the first corrosion inhibitor comprises 4-(3-phenylpropyl)pyridine.

In some embodiments of the composition, the second corrosion inhibitor comprises polyvinylpyrrolidone.

In some embodiments, a method of etching uses the composition described herein, and the method comprises removing TiN at a TiN removal rate of at least 5.0 nm per minute. In some embodiments of the method, the TiN removal rate is at least 10 nm per minute.

In some embodiments, the method further comprises removing Co at a Co removal rate of at least 20 nm per minute. In some embodiments of the method, the Co removal rate is at least 25 nm per minute.

In some embodiments of the method, a removal rate of a first material is less than 1.8 nm per minute due to protection via the first corrosion inhibitor. In some embodiments of the method, the first material is Cr, Mo, W, or any combination thereof.

In some embodiments of the method, a removal rate of a second material is less than 0.5 nm per minute due to protection via the second corrosion inhibitor.

### DETAILED DESCRIPTION

Among those benefits and improvements that have been disclosed, other objects and advantages of this disclosure will become apparent from the following description. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “microelectronic device” corresponds to semiconductor substrates, flat panel displays, phase change memory devices, solar panels and other products including solar cell devices, photovoltaics, and microelectromechanical systems (MEMS), manufactured for use in microelectronic, integrated circuit, energy collection, or computer chip applications. It is to be understood that the terms “microelectronic device,” “microelectronic substrate” and “microelectronic device structure” are not meant to be limiting in any way and include any substrate or structure that will eventually become a microelectronic device or microelectronic assembly. The microelectronic device can be patterned, blanketed, a control and/or a test device.

As used herein, the terms “titanium nitride” and “TiNₓ” correspond to pure titanium nitride as well as impure titanium nitride including varying stoichiometries, and oxygen content (i.e., TiOₓN_{y}).

As used herein, “about” is intended to correspond to + or −0.5% of the stated value.

As used herein, the term “low-k dielectric material” corresponds to any material used as a dielectric material in a layered microelectronic device, wherein the material has a dielectric constant less than about 3.5. In certain embodiments, the low-k dielectric materials include low-polarity materials such as silicon-containing organic polymers, silicon-containing hybrid organic/inorganic materials, organosilicate glass (OSG), TEOS, fluorinated silicate glass (FSG), silicon dioxide, aluminum oxides (AlOₓ), zirconium oxides (ZrOₓ), and carbon-doped oxide (CDO) glass. It should also be appreciated that the low-k dielectric materials may have varying densities and varying porosities.

As used herein, the term “metal conductor layers” comprise copper, tungsten, cobalt, molybdenum, aluminum, ruthenium, alloys comprising same, or combinations thereof.

As used herein, “fluoride” species correspond to species including an ionic fluoride (F⁻) or covalently bonded fluorine. It is to be appreciated that the fluoride species may be included as fluoride species or generated in situ.

Compositions of the invention may be embodied in a wide variety of specific formulations, as hereinafter more fully described.

In all such compositions, wherein specific components of the composition are discussed in reference to weight percentage ranges including a zero lower limit, it will be understood that such components may be present or absent in various specific embodiments of the composition, and that in instances where such components are present, they may be present at concentrations as low as 0.0001 weight percent, based on the total weight of the composition in which such components are employed.

In some embodiments, the present disclosure is directed towards compositions and processes for creating recesses within microelectronic device structures, for example 3D NAND flash memory devices. Some of the embodiments of the processes can be characterized to include a dry or wet etching process, and a process wherein a titanium nitride (TiN) layer is selectively etched, generally leaving some other materials present unaffected by the process, as well as any aluminum oxide, silicon dioxide, and polysilicon which may be present. In some embodiments, the process can have an improved etch rate and can provide a uniform recess top and bottom layers in patterns. In some embodiments, the compositions are quite stable, for example greater than 24 hours of bath life and greater than 6 months shelf life.

According to some embodiments, an exemplary material includes a TiN layer and a cobalt (Co) layer, where the TiN layer and the Co layer are to be selectively removed, generally leaving some other materials present unaffected by a process of chemical etching with an exemplary composition.

Some examples of the some other materials include, but are not necessarily limited to, a first material, a second material, a silicon-based material, etc. According to some embodiments, an example of the first material include molybdenum (Mo) or an alloy containing Mo. According to some embodiments, examples the first material is or includes Cr, Mo, W, an alloy containing Cr, an alloy containing Mo, an alloy containing W, or any combination thereof. According to some embodiments, examples of the silicon-based material include silicon (Si), SiOₓ, silicon oxide, SiNₓ, silicon nitride (SiₓN_{y}), polysilicon, or a combination thereof.

In some embodiments, the exemplary composition includes an oxidizing agent, an etchant, a first corrosion inhibitor, and a second corrosion inhibitor. The first corrosion inhibitor inhibits a chemical reaction of the oxidizing agent and/or the etchant with the first material. According to some embodiments, the composition selectively etches TiN and Co and does not etch (i.e., chemically react with) the first material (e.g., Mo), the chemical reaction does not result in or form an oxide of the first material (e.g., MoOₓ). According to some embodiments, the composition selectively etches TiN and Co and does not etch (i.e., chemically react with) the first material (e.g., Mo) because of the first corrosion inhibitor in the composition. Thus, the use of the composition does not result in or form an oxide of the first material (e.g., MoOₓ).

In some embodiments, the first corrosion inhibitor includes 5-methylbenzotriazole, benzotriazole, or a combination thereof.

In some embodiments, the first corrosion inhibitor is 5-methylbenzotriazole.

In some embodiments, the first corrosion inhibitor is benzotriazole.

Some embodiments of the composition further includes one or more pH adjustor(s) and a solvent (or a solvent solution). In some embodiments, the composition includes a solvent which is a water-miscible solvent. Some embodiments of the composition includes water (such as for example, deionized water). In some embodiments, the composition includes a water-miscible solvent and water (such as for example, deionized water). In some embodiments of the composition, the etchant is one or more TiN etching agent(s). In some embodiments of the composition, the etchant is or includes a TiN etching agent(s) and a Co etching agent(s). In some embodiments of the composition, the etchant is or includes one or more TiN and Co etching agent(s).

Further, for example, according to some embodiments, the material includes TiN layer disposed above a Co layer. The Co layer is disposed above a Mo layer (example of the first material). The Mo layer is disposed above a SiₓN_{y} material.

For example, according to some embodiments, the material includes TiN layer disposed above a Co layer. The Co layer is disposed above a Mo layer (example of the first material). The Mo layer is disposed above a SiOₓ material.

For example, according to some embodiments, the material includes TiN layer disposed above a Co layer. The Co layer is disposed above a Mo layer (example of the first material). The Mo layer is disposed above a Si material.

In some embodiments, the composition has a TiN etch rate of 5 nm per minute or higher (at 60° C.).

In some embodiments, the composition has a Co etch rate of 20 nm per minute or higher (at 60° C.).

In some embodiments, the composition has a TiN etch rate of 5 nm per minute or higher and a Co etch rate of 20 nm per minute or higher (at 60° C.).

An exemplary material includes a titanium nitride (TiN) layer and a cobalt (Co) layer, where the TiN layer and the Co layer are to be selectively removed, generally leaving some other materials present unaffected by a process of chemical etching with an exemplary composition.

Some examples of the some other materials include, but are not necessarily limited to, a first material, a second material, a silicon-based material, etc.

In some embodiments, the second material includes one or more of a transition metal.

In some embodiments, the exemplary composition includes an oxidizing agent, an etchant, a first corrosion inhibitor, and a second corrosion inhibitor. The first corrosion inhibitor inhibits a chemical reaction of the oxidizing agent and/or the etchant with the first material. The second corrosion inhibitor includes a N-hetero-atom-containing aromatic compound, which inhibits a chemical reaction of the oxidizing agent and/or the etchant with the second material.

For example, according to some embodiments, the material includes TiN layer disposed above a Co layer. The Co layer is disposed above the second material. The second material is disposed above a SiₓN_{y} material.

For example, according to some embodiments, the material includes TiN layer disposed above a Co layer. The Co layer is disposed above the second material. The second material is disposed above a SiOₓ material.

For example, according to some embodiments, the material includes TiN layer disposed above a Co layer. The Co layer is disposed above the second material. The second material is disposed above a Si material.

In some embodiments, at 60° C., the composition has a very high TiN etch selectivity. In some embodiments, the composition has a TiN etch rate of 5 nm per minute or higher, a Co etch rate of 20 nm per minute or higher, and the composition is compatible with Mo, SiₓN_{y}, and SiOₓ. In some embodiments, the composition does not etch Mo, SiₓN_{y}, and SiOₓ. In some embodiments, the composition is non-reactive with Mo, SiₓN_{y}, and SiOₓ

In some embodiments, at 60° C., the composition has a TiN etch rate of 5 nm per minute or higher, a Co etch rate of 20 nm per minute or higher, and the composition is compatible with Mo, SiₓN_{y}, and SiOₓ, or any combination thereof. In some embodiments, the composition does not etch Mo, SiₓN_{y}, and SiOₓ, or any combination thereof. In some embodiments, the composition is non-reactive with Mo, SiₓN_{y}, and SiOₓ, or any combination thereof.

In some embodiments, a portion of a material includes an exemplary material and another exemplary material, wherein each of the materials includes a titanium nitride (TiN) layer and a cobalt (Co) layer. The TiN layer and the Co layer are to be selectively removed, generally leaving some other materials present unaffected by a process of chemical etching with an exemplary composition.

Some examples of the some other materials include, but are not necessarily limited to, a first material, a second material, a silicon-based material, etc.

According to some embodiments, an example of the first material include molybdenum (Mo) or an alloy containing Mo. According to some embodiments, examples the first material is or includes Cr, Mo, W, an alloy containing Cr, an alloy containing Mo, an alloy containing W, or any combination thereof.

According to some embodiments, examples of the silicon-based material include silicon (Si), SiOₓ, silicon oxide, SiNₓ, silicon nitride (SiₓN_{y}), polysilicon, or a combination thereof.

In some embodiments, the exemplary composition includes an oxidizing agent, an etchant, a first corrosion inhibitor, and a second corrosion inhibitor. The first corrosion inhibitor inhibits a chemical reaction of the oxidizing agent and/or the etchant with the first material.

In some embodiments, the exemplary composition includes an oxidizing agent, an etchant, a first corrosion inhibitor, and a second corrosion inhibitor. The first corrosion inhibitor inhibits a chemical reaction of the oxidizing agent and/or the etchant with the first material. The second corrosion inhibitor includes a N-hetero-atom-containing aromatic compound, which inhibits a chemical reaction of the oxidizing agent and/or the etchant with the second material. The composition is compatible with, or non-reactive with the silicon-based material. That is, according to some embodiments, the composition reacts with TiN and Co at a much faster rate than with the silicon-based material such that the TiN and Co are removed much faster than the rate of removal of the silicon-based material, or the composition reacts with TiN and Co but does not react substantially with the silicon-based material, and thus, while TiN and Co are removed, the silicon-based material is not substantially removed, or the composition reacts with TiN and Co but does not react with the silicon-based material, and thus, while TiN and Co are removed, the silicon-based material is not removed.

In some embodiments, the composition is a TiN and Co etchant composition which comprises an oxidizing agent, an etchant, a first corrosion inhibitor, and a second corrosion inhibitor, wherein the first corrosion inhibitor includes 5-methylbenzotriazole and 4-(3-phenylpropyl)pyridine, and the second corrosion inhibitor includes polyvinylpyrrolidone. In some embodiments, the composition further comprises a pH adjustor and deionized water.

In some embodiments of the composition, the chemical reaction does not result in or form MoOₓ.

According to some embodiments, etchants contemplated include, but are not limited to, fluoride sources such as HF, ammonium fluoride, tetrafluoroboric acid, hexafluorosilicic acid, other compounds containing B—F or Si—F bonds, tetrabutylammonium tetrafluoroborate (TBA-BF₄), tetraalkylammonium fluoride (NR₁R₂R₃R₄F), strong bases such as tetraalkylammonium hydroxide (NR₁R₂R₃R₄OH), where R₁, R₂, R₃, R₄ may be the same as or different from one another and are chosen from hydrogen, straight-chained or branched C₁-C₆ alkyl groups (e.g., methyl, ethyl, propyl, butyl, pentyl, hexyl), C₁-C₆ alkoxy groups (e.g., hydroxyethyl, hydroxypropyl) substituted or unsubstituted aryl groups (e.g., benzyl), weak bases, or combinations thereof. In one embodiment, the fluoride source comprises HF, tetrafluoroboric acid, hexafluorosilicic acid, H₂ZrF₆, H₂TiF₆, HPF₆, ammonium fluoride, tetramethylammonium fluoride, tetramethylammonium hydroxide, ammonium hexafluorosilicate, ammonium hexafluorotitanate, or a combination of ammonium fluoride and tetramethylammonium fluoride. In another embodiment, the etchant comprises HF, hexafluorosilicic acid or tetrafluoroboric acid. In yet another embodiment, the etchant is HF.

According to some embodiments, oxidizing agents included to etch or oxidize Ti³⁺ in TiNₓ films. Oxidizing agents contemplated herein include, but are not limited to, hydrogen peroxide (H₂O₂), FeCl₃, FeF₃, Fe(NO₃)₃, Sr(NO₃)₂, CoF₃, MnF₃, Oxone® (2KHSO₅·KHSO₄·K₂SO₄—CAS No. 70693-62-8), periodic acid, iodic acid, t-butyl hydroperoxide, vanadium (V) oxide, vanadium (IV,V) oxide, ammonium vanadate, ammonium polyatomic salts (e.g., ammonium peroxomonosulfate, ammonium chlorite (NH₄ClO₂), ammonium chlorate (NH₄ClO₃), ammonium iodate (NH₄IO₃), ammonium nitrate (NH₄NO₃), ammonium perborate (NH₄BO₃), ammonium perchlorate (NH₄ClO₄), ammonium periodate (NH₄IO₄), ammonium persulfate ((NH₄)₂S₂O₈), ammonium hypochlorite (NH₄ClO)), ammonium tungstate ((NH₄)₁₀H₂(W₂O₇)), sodium polyatomic salts (e.g., sodium persulfate (Na₂S₂O₈), sodium hypochlorite (NaClO), sodium perborate), potassium polyatomic salts (e.g., potassium iodate (KIO₃), potassium permanganate (KMnO₄), potassium persulfate, nitric acid (HNO₃), potassium persulfate (K₂S₂O₈), potassium hypochlorite (KClO)), tetramethylammonium polyatomic salts (e.g., tetramethylammonium chlorite ((N(CH₃)₄)ClO₂), tetramethylammonium chlorate ((N(CH₃)₄)ClO₃), tetramethylammonium iodate ((N(CH₃)₄)IO₃), tetramethylammonium perborate ((N(CH₃)₄)BO₃), tetramethylammonium perchlorate ((N(CH₃)₄)ClO₄), tetramethylammonium periodate ((N(CH₃)₄)₁₀₄), tetramethylammonium persulfate ((N(CH₃)₄)S₂O₈)), tetrabutylammonium polyatomic salts (e.g., tetrabutylammonium peroxomonosulfate), peroxomonosulfuric acid, ferric nitrate (Fe(NO₃)₃), urea hydrogen peroxide ((CO(NH₂)₂)H₂O₂), peracetic acid (CH₃(CO)OOH), 1,4-benzoquinone, toluquinone, dimethyl-1,4-benzoquinone, chloranil, alloxan, or combinations thereof. When the oxidizing agent is a salt it can be hydrated or anhydrous. The oxidizing agent may be introduced to the composition at the manufacturer, prior to introduction of the composition to the device wafer, or alternatively at the device wafer, i.e., in situ. In one embodiment, the oxidizing agent comprises periodic acid.

The pH of the compositions can be adjusted using any suitable compound capable of adjusting the pH of the composition. The pH adjustor desirably is water-soluble and compatible with the other components of the composition. Typically, the composition has a pH of about −1 to 5, or 0-4, or 2 to 4 at the point-of-use. Non-limiting examples of pH adjustors include mineral acids and organic acids, including methane sulfonic acid, ethane sulfonic acid phosphoric acid, sulfuric acid, hydrogen chloride, etc.

In some embodiments, a solvent can comprise water, at least one water-miscible organic solvent, or a combination thereof, wherein the at least one water-miscible organic solvent is selected from the group consisting of a compound of formula R¹R²R³C(OH), where R¹, R² and R³ are independent from each other and are selected from to the group consisting of hydrogen, C₂-C₃₀ alkyls, C₂-C₃₀ alkenes, cycloalkyls, C₂-C₃₀ alkoxys, and combinations thereof. For example, the at least one solvent can comprise at least one species selected from the group consisting of water, methanol, ethanol, isopropanol, butanol, and higher alcohols, tetrahydrofurfuryl alcohol (THFA), 3-chloro-1,2-propanediol, 3-chloro-1-propanethiol, 1-chloro-2-propanol, 2-chloro-1-propanol, 3-chloro-1-propanol, 3-bromo-1,2-propanediol, 1-bromo-2-propanol, 3-bromo-1-propanol, 3-iodo-1-propanol, 4-chloro-1-butanol, 2-chloroethanol), dichloromethane, chloroform, acetic acid, propionic acid, trifluoroacetic acid, tetrahydrofuran (THF), N-methylpyrrolidinone (NMP), cyclohexylpyrrolidinone, N-octylpyrrolidinone, N-phenylpyrrolidinone, methyldiethanolamine, methyl formate, dimethyl formamide (DMF), dimethylsulfoxide (DMSO), tetramethylene sulfone (sulfolane), diethyl ether, phenoxy-2-propanol (PPh), propriophenone, ethyl lactate, ethyl acetate, ethyl benzoate, acetonitrile, acetone, ethylene glycol, propylene glycol (PG), 1,3-propanediol, 1,4-propanediol, dioxane, butyryl lactone, butylene carbonate, ethylene carbonate, propylene carbonate, dipropylene glycol, diethylene glycol monomethyl ether, triethylene glycol monomethyl ether, diethylene glycol monoethyl ether, triethylene glycol monoethyl ether, ethylene glycol monopropyl ether, ethylene glycol monobutyl ether, diethylene glycol monobutyl ether (i.e., butyl carbitol), triethylene glycol monobutyl ether, ethylene glycol monohexyl ether, diethylene glycol monohexyl ether, ethylene glycol phenyl ether, propylene glycol methyl ether, dipropylene glycol methyl ether (DPGME), tripropylene glycol methyl ether (TPGME), dipropylene glycol dimethyl ether, dipropylene glycol ethyl ether, propylene glycol n-propyl ether, dipropylene glycol n-propyl ether (DPGPE), tripropylene glycol n-propyl ether, propylene glycol n-butyl ether, dipropylene glycol n-butyl ether, tripropylene glycol n-butyl ether, propylene glycol phenyl ether, dipropylene glycol methyl ether acetate, tetraethylene glycol dimethyl ether (TEGDE), dibasic ester, glycerine carbonate, N-formyl morpholine, triethyl phosphate, or combinations thereof. In one embodiment, the at least one solvent comprises water, for example, deionized water. In one embodiment, the water-miscible solvent is chosen from ethylene glycol and propylene glycol.

A nonlimiting exemplary composition is described below:

Example Composition

| | | |
|---|---|---|
| Methanesulfonic acid (MSA) | 1~10 | wt % |
| Periodic acid (PIA) 0.5% | 1~4 | wt % |
| HF 0.49% | 2~20 | wt % |
| 4-(3-Phenyl)propylpyridine (PPP) | 0.01~10 | wt % |
| Polyvinylpyrrolidone (PVP) 0.1% | 0.01~10 | wt % |
| 1,2,3-Benzotriazole | 0.01~1 | wt % |

| | |
|---|---|
| DIW (deionized water) | Balance |

When the above Example Composition was used (etching at 60° C.), the TiN etching rate of over 10 nm/min was achieved. The same Example Composition was used to also produce a Co etch rage of 28.9 nm/min or higher. Further, Mo etch rate of less than 1.8 nm/min could be achieved. Under some situations, the Mo etch rate of less than 1.5 nm/min could be achieved. Under some situations, the Mo etch rate of less than 0.7 nm was achieved. SiNₓ etch rate of less than 0.1 nm/min was also achievable.

What is claimed is:

1. A composition comprising:
an oxidizing agent;
an etchant;
a first corrosion inhibitor; and
a second corrosion inhibitor,
wherein the second corrosion inhibitor includes a N-hetero-atom-containing aromatic compound.

2. The composition of claim 1, wherein the first corrosion inhibitor inhibits chemical reaction of a first material, wherein the first material includes Cr, Mo, W, or any combination thereof.

3. The composition of claim 1, wherein the second corrosion inhibitor inhibits chemical reaction of a second material.

4. The composition of claim 1, wherein the first corrosion inhibitor comprises 5-methylbenzotriazole.

5. The composition of claim 4, wherein the second corrosion inhibitor comprises polyvinylpyrrolidone.

6. The composition of claim 4, wherein the first corrosion inhibitor comprises 4-(3-phenylpropyl)pyridine.

7. The composition of claim 6, wherein the second corrosion inhibitor comprises polyvinylpyrrolidone.

8. The composition of claim 1, wherein the first corrosion inhibitor comprises 4-(3-phenylpropyl)pyridine.

9. The composition of claim 8, wherein the second corrosion inhibitor comprises polyvinylpyrrolidone.

10. The composition of claim 1, wherein the second corrosion inhibitor comprises polyvinylpyrrolidone.

11. A method of etching using the composition according to claim 1, the method comprising:
removing TiN at a TiN removal rate of at least 5.0 nm per minute.

12. The method of claim 11, further comprising:
removing Co at a Co removal rate of at least 20 nm per minute.

13. The method of claim 12, wherein the TiN removal rate is at least 10 nm per minute.

14. The method of claim 13, wherein the Co removal rate is at least 25 nm per minute.

15. The method of claim 14, wherein a removal rate of a first material is less than 1.8 nm per minute due to protection via the first corrosion inhibitor.

16. The method of claim 15, wherein the first material is Cr, Mo, W, or any combination thereof.

17. The method of claim 16, wherein a removal rate of a second material is less than 0.5 nm per minute due to protection via the second corrosion inhibitor.

18. The method of claim 17, wherein the second material is any one or more of a Group 9 transition metal.

19. The method of claim 14, wherein a removal rate of a second material is less than 0.5 nm per minute due to protection via the second corrosion inhibitor.

20. The method of claim 19, wherein the second material is any one or more of a Group 9 transition metal.
